(19) United States
(12) Patent Application Publication
(10) Pub. No.: US 2006/0242518 A1
(43) Pub. Date: Oct. 26, 2006

(54) Method for verification of electronic circuit units, and an apparatus for carrying out the method

(75) Inventors: Sven Boldt, Aschheim (DE); Erwin Thalmann, Villach (AT)

Correspondence Address: Maginot, Moore & Beck;Bank One Tower, Suite 3000, 111 Monument Circle, Indianapolis, IN, 46204, US

(73) Assignee: Infineon Technologies AG, Munchen (DE)

(21) Appl. No.: 11/111,459

(22) Filed: Apr. 21, 2005

(30) Foreign Application Priority Data
Apr. 21, 2005 (DE) 10 2004 019 367.3

(51) Int. Cl. G01R 31/28

(52) U.S. Cl. 714/732

(57) ABSTRACT

The invention relates to a method for verification of electronic circuit units (101) which are contained in a circuit apparatus (100) with the operating state of the electronic circuit unit (101) to be verified being read by means of the circuit apparatus (100), an identification key (102, HWID) being read from the electronic circuit unit (101) to be verified, a reference identification key (105) being transmitted (S5) to the circuit apparatus (100), the identification key (102) being compared (S6) with the reference identification key (105), and a message for a user being emitted (S6) when the identification key (102) read from the electronic circuit unit (101) to be verified does not match the transmitted reference identification key (105).

The present invention relates in general to verification of electronic circuit units, and relates in particular to a method for verification of an electronic circuit unit which is supplied by a specific manufacturer and is installed in a circuit apparatus in an end user (user) appliance.

In particular, the verification process according to the invention relates to the following steps:

a) reading the operating state of the electronic circuit unit to be verified by means of the circuit apparatus which contains the electronic circuit unit to be verified;

b) reading by means of the circuit apparatus, an identification key from the electronic circuit unit to be verified;

c) transmission of a reference identification key to the circuit apparatus which contains the electronic circuit unit to be verified;

d) comparison of the identification key, read by means of the circuit apparatus from the electronic circuit unit to be verified, with the reference identification key transmitted to the circuit apparatus which contains the electronic circuit unit to be verified; and

e) indication of a message for a user when the identification key read from the electronic circuit unit to be verified does not match the reference identification key transmitted to the circuit apparatus which contains the electronic circuit unit to be verified, or ending the verification process when the identification key read from the electronic circuit unit to be verified matches the reference identification key transmitted to the circuit apparatus which contains the electronic circuit unit to be verified.

Electronic circuit units such as DRAM modules (Dynamic Random Access Memory) are used for the construction of memory apparatuses. System information such as a memory size or a speed class of the relevant electronic circuit unit is stored permanently in a solid-state memory unit which, by way of example, is in the form of an EEPROM (Electronically Erasable Programmable Read Only Memory).

A solid-state memory such as this is located within the electronic circuit unit. The electronic circuit units, such as the electronic memory modules, are predominantly used in computer systems (PCs, servers). When this computer system is started, then, inter alia, the system information is read from the memory module in order to signal to the system the type and class of memories with which it is equipped.

One major disadvantage of conventional circuit apparatuses which contain such electronic circuit units is that the information contained in the solid-state memory (EEPROM) may be corrupted, that is to say, by way of example, a speed class could be changed. It would then not be possible for the end user (user) to check the presence of a correct memory module. Since higher speed classes result in higher purchase prices for memory modules, and the electronic circuit units which are used in the computer system cannot be checked by the user, there is a risk of falsification in order to achieve a financial advantage. Use of such falsified components in the electronic circuit units disadvantageously results in system instabilities.

Furthermore, the electronic circuit units (for example the memory modules) are provided with stickers, which can likewise easily be falsified in order to simulate higher-quality electronic circuits units, which achieve a higher purchase price on the market. If the computer system (system) cannot identify the false memory modules, this can lead to instabilities, particularly when moving through a wide temperature range.

In this case, it is normally possible for the system to operate correctly in a stable ambient temperature, while it cannot operate correctly in accordance with the specification when major temperature fluctuations occur as, in particular, in the case of the use of portable systems.

The major components of a memory module are the memory components. If these components were false, then the user would likewise not have a capability to detect this. Falsification would in this case mean that components with stringent requirements for function and stability could be replaced by lower-quality and thus cheaper components.

A major disadvantage of known electronic circuit units is thus that both the information which is stored in the solid-state memory (EEPROM) and the information contained on a sticker which is fitted to the electronic circuit unit can easily be falsified. This leads to the problem that circuit apparatuses which contain the electronic circuit units cannot be operated in accordance with the intended specification, and/or that, when the circuit apparatuses are operated in accordance with the electronic specification, there is then a possibility of system instabilities occurring.

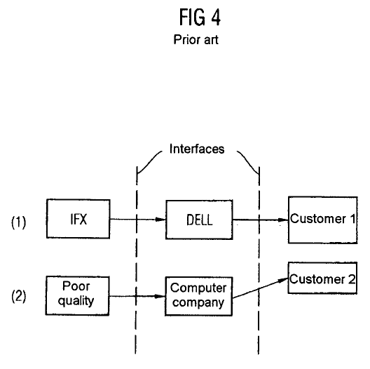

FIG. 4 shows the conventional product flow on the basis of two examples (1) and (2), with two interfaces being indicated by way of example (dashed lines) which have to be overcome by an electronic circuit unit before it can be used by an end user (user, customer).

(1) A Customer 1 Receives a Full-Quality Product

A chip manufacturer IFX supplies an electronic circuit unit with verified specifications via a first interface to a system manufacture DELL who, for example, assembles computer systems. Via a further interface (second interface), the customer 1 receives a full-quality product (computer system), which contains a fully functional chip (electronic circuit unit).

(2) A Customer 2 Receives a Product of Reduced Quality

A chip manufacturer supplies a poor quality or an unverified product to a computer system company (computer company) which fits the unverified chip (the unverified electronic circuit unit) in a computer system and, in some circumstances, falsifies the details of the performance data of the electronic circuit unit. After a system which has the unverified electronic circuit unit has been assembled, the customer 2 (after the second interface) receives an unverified computer system. In some circumstances, this may operate correctly, but the customer 2 does not have the capability to check whether the chips contained in the computer system satisfy, for example, the specified speed classes.

The problem thus exists that falsifications in the production of components or in the production of computer systems cannot be identified. Falsifications such as these include, inter alia, a reduced quality of the components used (of the electronic circuit units used) or incorrect (falsified) details of system parameters.

A further disadvantage is that systems with electronic circuit units of a reduced quality can be used only over a restricted range of operating temperatures (for example only at room temperature), because the system becomes unstable in other operating ranges.

For the user (end user), this results in the major financial disadvantage that he may possibly have paid a high price for a reduced product quality. The end user (user) disadvantageously does not have the capability to verify that information which can be found in the solid-state memory of a memory module or on its sticker.

One object of the present invention is thus to provide a method for verification of electronic circuit units after they have been installed in a circuit apparatus designed for the user.

According to the invention, this object is achieved by a method as specified in patent claim 1.

The object is also achieved by an apparatus having the features of patent claim 7, and by an electronic circuit unit, which is provided with a verification key, as claimed in claim 9.

Further refinements of the invention can be found in the dependent claims.

One major idea of the invention is for the electronic circuit units to be verified to be provided with unique hardware keys and/or hardware identification units which can be used for the verification of manufacturer and system parameter information items in the final system (user system). Hardware keys such as these comprise identification keys (HWID, Hardware identification), which comprise a manufacturer key and a unique key, (chip-specific key), which is specific for the electronic circuit unit to be verified).

One major advantage of the present invention is thus that modifications/falsifications, or falsifications of information items, which are carried out in the solid-state memory and/or on the sticker of the electronic circuit unit to be verified can be identified and corrected.

A further advantage of the present invention is that the electronic circuit units which are used in a circuit apparatus (a system, for example a computer system) can be allocated uniquely to one manufacture. This provides quality assurance.

It is also possible to carry out a check of system parameters, for example of the operating frequency, independently of the information in the solid-state memory or on the sticker.

The definition of a unique identification key for each electronic circuit unit sold also results in the advantage that information about the purchased components is available at all times. The information stored in an information key database about each individual delivered electronic circuit unit can be checked by an end user (end customer), advantageously via the Internet.

The specific advantage for the end customer is, in particular, that he can carry out a quality check in his system, that is to say the presence of high-quality, quality, and thus more expensive, components can now be checked on the basis of a unique identification key for each delivered electronic circuit unit.

The method according to the invention for verification of one more electronic circuit units to be verified which are contained in a circuit arrangement or in a system, in one verification process, essentially comprises the following steps:

a) reading, by means of the circuit apparatus, the operating state of the electronic circuit unit to be verified;

b) reading, by means of the circuit apparatus, an identification key from the electronic circuit unit to be verified;

c) transmission of a reference identification key to the circuit apparatus which contains the electronic circuit unit to be verified;

d) comparison of the identification key, read by means of the circuit apparatus from the electronic circuit unit to be verified, with the reference identification key transmitted to the circuit apparatus which contains the electronic circuit unit to be verified; and

e) indication of a message for a user when the identification key read from the electronic circuit unit to be verified does not match the reference identification key transmitted to the circuit apparatus which contains the electronic circuit unit to be verified, or ending the verification process when the identification key read from the electronic circuit unit to be verified matches the reference identification key transmitted to the circuit apparatus which contains the electronic circuit unit to be verified.

The apparatus according to the invention for verification of one or more electronic circuit units to be verified, by means of a verification process, also essentially comprises:

a) a circuit apparatus which contains the circuit unit to be verified, with the circuit apparatus having:

a1) a first read unit for reading the operating state of the electronic circuit unit to be verified; and

a2) a second read unit for reading an identification key from the electronic circuit unit to be verified;

b) a transmission unit for transmission of a reference identification key to the circuit apparatus which contains the electronic circuit unit to be verified;

c) a comparison unit for comparison of the identification key, which has been read by means of the circuit apparatus from the electronic circuit unit to be verified, with the reference identification key which is transmitted to the circuit apparatus which contains the electronic circuit unit to be verified; and

d) an indication unit for indication of a message to a user when the identification key which has been read from the electronic circuit unit to be verified does not match the reference identification key transmitted to the circuit apparatus which contains the electronic circuit unit to be verified, with the verification process being ended when the identification key read from the electronic circuit unit to be verified matches the reference identification key transmitted to the circuit apparatus which contains the electronic circuit unit to be verified.

According to a further aspect of the present invention, an electronic circuit unit is provided which is equipped with a verification key for carrying out a verification process.

Advantageous developments and improvements of the respective subject matter of the invention can be found in the dependent claims.

According to one preferred development of the present invention, the identification key is formed from a manufacturer key and a chip-specific key. An identification key such as this advantageously uniquely identifies the electronic circuit unit to be verified.

According to a further preferred development of the present invention, the reference identification key is defined by a manufacturer of the electronic circuit unit to be verified.

According to yet another preferred development of the present invention, the reference identification key is transmitted via an Internet communication to the circuit apparatus which contains the electronic circuit unit to be verified.

According to yet another preferred development of the present invention, the reference identification key is provided for the circuit arrangement which contains the electronic circuit unit to be verified by means of a written communication, for example by sending the information by post.

According to yet another preferred development of the present invention, the verification process for the circuit apparatus which contains the electronic circuit unit to be verified is carried out automatically by means of the Internet communication.

According to a further aspect of the present invention, the electronic circuit unit to be verified is in the form of a DRAM (Dynamic Random Access Memory) module.

Exemplary embodiments of the invention will be explained in more detail in the following description, and are illustrated in the drawings, in which:

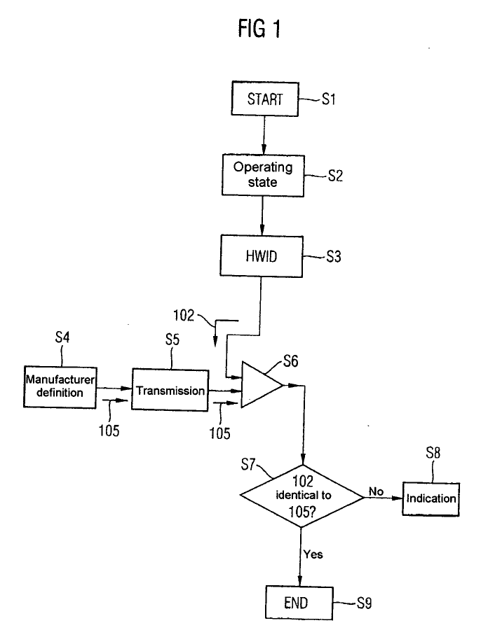

FIG. 1 shows a flowchart of a verification process for verification of an electronic circuit unit to be verified, according to one preferred exemplary embodiment of the present invention;

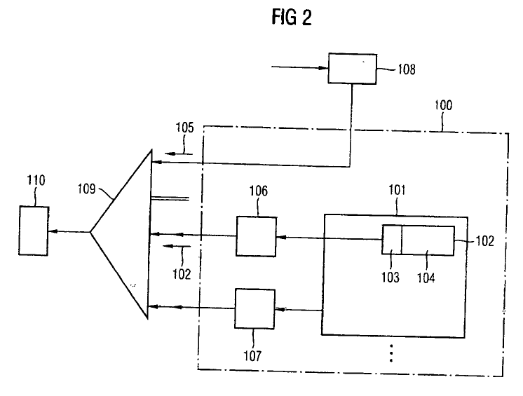

FIG. 2 shows an apparatus for verification of a circuit unit to be verified by means of the verification process illustrated schematically in FIG. 1, according to one preferred exemplary embodiment of the present invention;

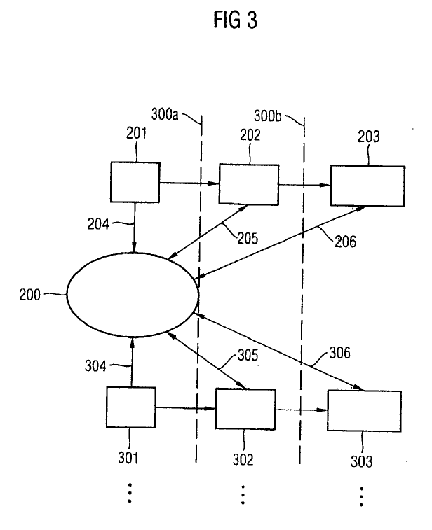

FIG. 3 shows a product flow diagram, which schematically illustrates the product flow from circuit unit manufacturers to users (end customers), according to one preferred exemplary embodiment of the present invention; and

FIG. 4 shows a conventional product flow from circuit unit manufacturers to customers 1, 2.

Identical reference symbols in the figures denote identical or functionally identical components or steps.

First of all, with reference to FIG. 1, the following text explains one preferred flow chart based on the verification process for verification of an electronic circuit unit to be verified, according to one preferred exemplary embodiment of the present invention.

Once the verification process has been started in a step S1, an operating state of the electronic circuit unit 101 to be checked is read by a first read unit 106 (described in the following text with reference to FIG. 2).

The operating state provides information, for example, about the speed class in which the electronic circuit unit 101 to be verified is currently being operated.

In a subsequent step S3, a verification key 102 (see below, FIG. 2) is read from the electronic circuit unit 101 to be verified. This verification key 102 is passed to a comparison unit 109, and is compared in a step S6 with a reference identification key 105. The reference identification key 105 is defined by a manufacturer in a step S4, and is transmitted to the comparison unit 109 (see below, FIG. 2) in a step S5.

The processing then continues to a step S7, in which a check is carried out to determine whether the identification key 102 read from the electronic circuit unit 101 to be verified is identical to the reference identification key 105 defined by the manufacturer.

If the identification key 102 read from the electronic circuit unit 101 to be verified does not match the reference identification key 105 which is transmitted to the circuit apparatus 100 which contains the electronic circuit unit 101 to be verified (“no” in step S7), an indication for a user is provided in the step S8 that an error or a falsification has occurred, that is to say the user is provided with an indication that the electronic circuit unit 101 provided by the manufacturer has not been installed in the system (computer system).

If it is found in the step S7 that the identification key 102 read from the electronic circuit unit 101 to be verified matches the transmitted reference identification key 105 (“yes” in step S7), the verification process is ended in a step S9.

By way of example, FIG. 2 shows a circuit apparatus 100 which contains one or more electronic circuit units 101 to be verified.

According to the invention, the electronic circuit unit to be checked is provided with an identification key 102 which is subdivided into a manufacturer key 103 and a chip-specific key 104. The identification key 102 uniquely identifies an electronic circuit unit produced by a manufacturer 201, 301 (described in the following text with reference to FIG. 3).

It should be noted that two or more different electronic circuit units 101 to be verified may be arranged in one circuit apparatus 100. The method according to the invention can be used for each individual electronic circuit unit 101 to be verified, provided that it is provided with a specific identification key 102.

A first read unit 106 is provided in order to read the unique identification key 102 from the electronic circuit unit 101 to be verified, while a second read unit 107 is used to read the operating state of the electronic circuit unit 101 to be verified. The comparison unit 109 mentioned above may be provided within or outside the circuit apparatus 101.

The comparison unit 109 is supplied via transmission unit 108 with the reference identification key, which is defined by the manufacture of the electronic circuit unit to be verified. A check is carried out in the comparison unit 109 to determine whether the reference identification key 105 matches the identification key 102 read from the electronic circuit unit 101 to be verified.

Furthermore, the operating state which is read via the second read unit 107 from the electronic circuit unit 101 to be verified can be checked with the aid of a signal which is supplied via the transmission unit 108. The result of a check such as this or of a comparison such as this is passed to an indication unit 110. The indication unit provides a message (error message, falsification message) for a user when the identification key 102 which has been read from the electronic circuit unit 101 to be verified does not match the reference identification key transmitted to the circuit apparatus 100 which contains the electronic circuit unit 101 to be verified.

FIG. 3 shows a diagram, schematically illustrating a product flow of manufactured electronic circuit units from circuit unit manufacturers 201, 301 to first and second users 203, 303. According to the invention, all of the reference identification keys 105 for all of the electronic circuits units 101 produced by the circuit unit manufacturers 201, 301 are stored in an identification key database 200.

It should be mentioned that, just by way of example, FIG. 3 shows first and second circuit unit manufacturers 201 and 301, first and second circuit apparatus manufacturers 202 and 302 (system manufacturers), respectively, as well as first and second users 203 and 303, respectively, although this does not restrict the present invention to two circuit unit manufacturers, two circuit apparatus manufacturers or two users.

Depending on the size of the identification key database 200, any desired number of circuit unit manufacturers 201, 301 . . . can store their reference identification keys 105 for electronic circuit units 101 to be verified in the identification key database 200.

The advantage of the method according to the invention for verification of one or more electronic circuit units 101 to be verified is now, as shown in FIG. 3, that specific interfaces between circuit unit manufacturers and circuit apparatus manufacturers 201 and 202 are also crossed, that is to say the interface 300a in FIG. 3, via first communication links 205, 305, allows the reference identification key 105 from the identification key database to be checked, for example via the Internet.

This allows the first and second circuit apparatus manufacturers 202 and 302, as shown in FIG. 3, to verify the electronic circuit unit 101 which is to be verified and is to be installed in the circuit apparatus 100.

A similar situation occurs after passing through the second interface 300b. The first and second users 203 and 303, respectively, can check via respective second communication links 206 and 306 whether the electronic circuit units 101 used in their circuit apparatus (for example a computer system) comply with the specifications, or whether these have been falsified.

The reference identification keys 105 are likewise passed to the identification key database 200 via the first and second communication links 204 and 304, respectively, from the respective first and second circuit apparatus manufacturers 201 and 301.

The method according to the invention for verification of electronic circuit units 101 to be verified results in a significant financial advantage in that it is possible to verify those performance classes of electronic circuit units which are also paid for by a user.

Although the present invention has been described above with reference to preferred exemplary embodiments, it is not restricted to these but can be modified in many ways.

With regard to the conventional product flow as illustrated in FIG. 4, reference should be made to the introduction to the description.

Furthermore, the invention is not restricted to the stated application options.

1-9. (canceled)

10. A method for verification of at least one electronic circuit unit contained in a circuit apparatus, the method comprising:
a) reading an operating state of the electronic circuit unit using the circuit apparatus;
b) reading an identification key from the electronic circuit unit using the circuit apparatus;
c) transmitting a reference identification key to the circuit apparatus which contains the electronic circuit unit;
d) comparing the identification key read from the electronic circuit unit with the reference identification key transmitted to the circuit apparatus; and
e) indicating a message when the identification key read from the electronic circuit unit does not match the reference identification key transmitted to the circuit apparatus or ending the method for verification when the identification key read from the electronic circuit unit matches the reference identification key transmitted to the circuit apparatus.

11. The method of claim 10 wherein the identification key comprises a manufacturer key and a chip-specific key.

12. The method of claim 10 wherein the reference identification key is defined by a manufacturer of the electronic circuit unit.

13. The method of claim 10 wherein the reference identification key is transmitted via an Internet communication to the circuit apparatus which contains the electronic circuit unit.

14. The method of claim 10 wherein the reference identification key is provided by a written communication.

15. The method of claim 13 wherein the method for verification is carried out automatically by means of Internet communication by the circuit apparatus which contains the electronic circuit unit.

16. The method of claim 10 wherein the at least one electronic circuit unit comprises at least one electronic memory module.

17. The method of claim 16 wherein the at least one electronic memory module comprises a DRAM memory module.

18. The method of claim 10 wherein the circuit apparatus comprises a computer system.

19. The method of claim 10 wherein the operating state of the electronic circuit unit comprises information about a speed class in which the electronic circuit unit operates.

20. An apparatus for verification of at least one electronic circuit to be verified, the apparatus comprising:
a) a circuit apparatus comprising the circuit unit to be verified, the circuit apparatus including
i) a first read unit operable to read an operating state of the electronic circuit unit to be verified; and
ii) a second read unit operable to read an identification key from the electronic circuit unit to be verified;
b) a transmission unit operable to transmit a reference identification key to the circuit apparatus;
c) a comparison unit operable to compare the identification key from the electronic circuit unit to be verified with the reference identification key; and
d) an indication unit operable to provide a message when the identification key from the electronic circuit unit to be verified does not match the reference identification key transmitted to the circuit apparatus.

21. The apparatus of claim 20 wherein the electronic circuit unit to be verified comprises at least one electronic memory module.

22. The method of claim 21 wherein the at least one electronic memory module comprises a DRAM memory module.

23. the method of claim 20 wherein the circuit apparatus comprises a computer system.

24. The method of claim 20 wherein the operating state of the electronic circuit unit to be verified comprises information about a speed class in which the electronic circuit unit operates.

25. The method of claim 20 wherein the message is an error message.

26. A method for verification of at least one memory module included in a computer system, the method comprising:
a) obtaining an identification key from the memory module;
b) transmitting a reference identification key to the computer system which includes the memory module;
c) comparing the identification key from the memory module with the reference identification key transmitted to the computer system; and
d) providing a message when the identification key from the memory module does not match the reference identification key transmitted to the computer system.

27. The method of claim 26 further comprising the step of ending the verification process when the identification key from the memory module matches the reference identification key transmitted to the computer system.

28. The method of claim 26 further comprising the step of obtaining an operating state of the memory module.

29. The method of claim 26 wherein the reference identification key is defined by a manufacturer of the memory module.
